(19) United States
(12) Patent Application Publication
(10) Pub. No.: US 2008/0203506 A1
(43) Pub. Date: Aug. 28, 2008

(54) Capacitive Junction Modulator, Capacitive Junction And Method For Making Same

(76) Inventors: Sylvain David, Courson-Monteloup (FR); Emmanuel Hadji, Fontaine (FR)

Correspondence Address: BRINKS HOFER GILSON & LIONE, P.O. BOX 10395, CHICAGO, IL, 60610, US

(21) Appl. No.: 11/721,791

(22) PCT Filed: Dec. 14, 2005
(86) PCT No.: PCT/FR05/03128

§ 371 Date: Aug. 21, 2007

(30) Foreign Application Priority Data
Dec. 16, 2004 (FR) 0413422

(51) Int. Cl. H01L 31/0352

(52) U.S. Cl. 257/431; 438/90; 257/E31.039

(57) ABSTRACT

The invention concerns a capacitive junction including a region adapted to be traversed by an electromagnetic wave, and a dielectric layer interposed between two semiconductor material layers. The dielectric layer has a reduced thickness at the region, that is a thickness at the region less than its thickness at a contact of the junction. Such a junction is for instance used to form a modulator. The invention also concerns a method for making such a junction.

The invention concerns a capacitive junction modulator, for example an optical modulator, a capacitive junction, and a method for making same.

By modulator is meant a device adapted to vary the intensity of an electromagnetic wave (for example light) passing through it, possibly in a binary manner; it can therefore be a switch.

There is nowadays a requirement for modulators (especially optical modulators) that can be integrated into microelectronic circuits, that is to say obtained by means directly applicable to silicon fabrication processes.

In this context, it has been proposed to use the physical property whereby the refractive index of a material can be modified by varying the density of the carriers in that material.

This property is used, for example, in pn type capacitive junctions consisting of an oxide barrier disposed between two layers of silicon that are respectively p-doped and n-doped. A solution of this type is described in the paper “A high-speed silicon optical modulator based on a metal-oxide-semiconductor capacitor”, by A. Liu et al., Nature, vol. 427, Feb. 12, 2004, for example.

In solutions of this type, the electrical contacts are formed by materials or by strong doping causing high optical losses and it is therefore desirable for these electrical contacts to be far away from the region in which the light crosses the capacitive junction in order to reduce the optical losses of the component.

For a given carrier density at the capacitive junction, this distancing generates an increase in the power consumed, especially in the case where the capacitive junction extends from the region in which the light crosses it to the electrical contacts.

What is more, the layer of silicon deposited on the silicon oxide barrier layer is polycrystalline; this property generates optical losses.

The invention is therefore directed in particular to a capacitive junction modulator the electrical contacts whereof can be sufficiently far away from the region of the capacitive junction crossed by the electromagnetic wave without this distancing causing any problematic increase in the power consumed for a given carrier density in the same region.

The invention proposes a modulator including a capacitive junction crossed by an electromagnetic wave, the capacitive junction comprising a dielectric layer disposed between two semiconductor material layers, characterized in that the dielectric layer has a reduced thickness in the area of the electromagnetic wave, i.e. in that the dielectric layer has a thickness that is (strictly) smaller in this area compared to its thickness in the area of the contact of the junction.

Reducing the thickness of the dielectric layer leads to the localized formation of a more intense electric field, enabling a higher concentration of charge carriers in this region crossed by the electromagnetic wave.

In other words, for a given concentration of carriers in the region crossed by the electromagnetic wave, there will be a lower concentration of carriers outside that region and consequently a reduced electrical power consumption of the junction.

In accordance with particularly practical implementation options that may where appropriate be combined, at least one of said semiconductor material layers is doped, at least one of said semiconductor material layers is formed from silicon, and the dielectric layer is formed from silicon oxide or insulative polymer. The silicon layers are advantageously monocrystalline in order to limit optical losses.

Each of said semiconductor material layers can have a thickness from 30 nm to 500 nm and the dielectric layer can have a thickness from 2 nm to 30 nm outside said thickness reduction. Such dimensions further facilitate integration of the modulator into a system produced in thin layers.

According to one implementation option, the thickness reduction is greater than 20%, for example from 20% to 60%, in order to generate the effect described hereinabove optimally. For example, for a dielectric layer 30 nm thick outside the thickness reduction, a 60% thickness reduction leads to a reduced thickness of approximately 10 nm.

To improve further the efficiency of the modulator, and in accordance with a concept that is novel in itself, the modulator can include a plurality of dielectric layers separated by layers formed from semiconductor material and at least part of each of which is crossed by the electromagnetic wave.

Thus a stack of capacitive junctions is used, as it were, which multiplies the modulation effect in the direction of the thickness of the layers.

The invention also proposes a capacitive junction as such that comprises a region adapted to be crossed by an electromagnetic wave, the capacitive junction comprising a dielectric layer disposed between two semiconductor material layers, characterized in that the dielectric layer has a reduction in thickness in said region, i.e. in that its thickness in the area of said region is (strictly) smaller than its thickness in the area of a contact of the junction.

The proposed capacitive junction can also have the optional features already described for the capacitive junction of the modulator and the advantages stemming therefrom.

The invention finally proposes a method of producing a capacitive junction, characterized in that it comprises the following steps;

etching a region of a layer situated in contact with a semiconductor material, said etching being initiated in said layer outside said region,

filling the etched space with a dielectric material.

According to one implementation option, said layer is disposed between two layers of semiconductor material which then form the capacitive junction with the dielectric material.

Each of said semiconductor material layers has a thickness from 30 nm to 500 nm, for example.

Said layer has a thickness from 1 nm to 15 nm which, after etching and filling, produces a dielectric layer from 2 nm to 30 nm thick, as indicated hereinabove.

According to one implementation option of the method, the latter further includes a step of formation of access holes to said layer outside said region, the etching being initiated via these holes.

This solution is particularly practical, especially if the capacitive junction is used as a modulator in a photonic crystal the holes whereof may be produced during said step of forming holes.

Other features and advantages of the invention will become more apparent in the light of the following description with reference to the appended drawings, in which:

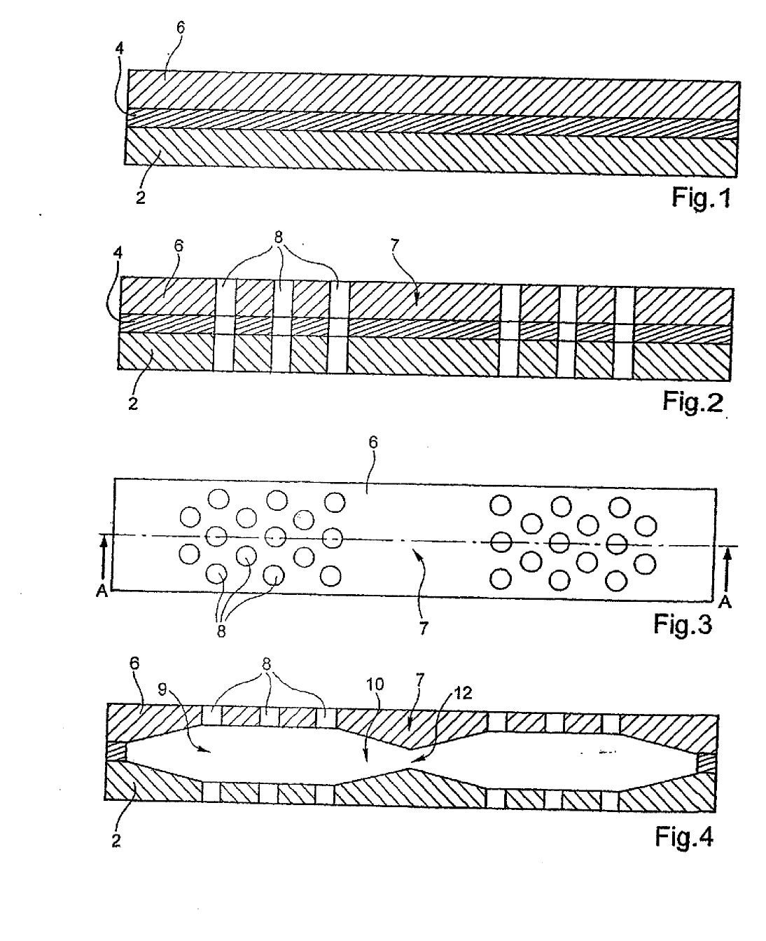

FIGS. 1 to 7 represent a method for producing a capacitive junction for an optical modulator according to a first embodiment of the invention;

FIG. 8 represents a stack of capacitive junctions conforming to a second embodiment of the invention.

A first embodiment of the invention is described next with reference to FIGS. 1 to 7.

FIG. 1 represents a structure formed by a stack of layers that comprises:

a first layer 2 of semiconductor material, for example of p-doped silicon (referred to hereinafter as the “Si-p layer”), which could be a substrate, for example, but the thickness whereof is limited here, for example to 500 nm;

a second layer 4 that covers the first layer 2 and is produced in a material relatively similar to that of the first layer (here silicon-germanium SiGe, for example) but which is easier to eliminate, as described hereinafter, with a thickness from 1 nm to 15 nm, for example;

a third layer 6 produced in semiconductor material, here in n-doped silicon (this third layer 6 therefore being referred to hereinafter as the “Si-n layer”), 50 nm thick, for example.

The layered structure is produced by successive deposition of the second layer 4 and the third layer 6 onto the first layer 2, for example, or by epitaxial growth to obtain monocrystalline second and third layers 4, 6.

The layered structure is deposited on a substrate that provides mechanical strength, for example an SOI (“Silicon On Insulator”) substrate or a quartz substrate.

Holes 8, for example cylindrical holes, are produced in the structure that has just been described, specifically in two regions thereof separated by a central region 7, with their axes perpendicular to the free surface of the third layer 6 (i.e. also to the interface between each pair of layers), which extend vertically over the whole of the depth of the third layer 6, the second layer 4 and the first layer 2.

Each of the regions separated by the central region 7 includes a plurality of holes (typically of the order of magnitude of about ten holes or a few tens of holes), which provides access from the exterior (i.e. the free face of the third layer 6) to the second layer 4 over the whole of the aforementioned region, preserving the general mechanical structure of the third layer 6 in this same region.

This set of holes could equally be provided by the presence of a photonic crystal the holes wherein can be of circular, square or other shape section according to the required properties of the photonic crystal. This set of holes can equally take the form of repetition of the same hole, a set of holes or a compact aperiodic (i.e. non-periodic) structure.

However, for reasons of convenience of production, it might be preferred to produce the holes of cylindrical or square section in accordance with a simple periodic triangular or square array in which each hole is advantageously of sub-micron size.

There is obtained in this way the structure represented in section on a vertical plane A-A in FIG. 2 and seen from above in FIG. 3.

There follows the next step which consists in attacking the second layer 4 (produced in SiGe in the example described here) by etching it, for example by wet etching it by means of a mixture of hydrofluoric acid, acetic acid and hydrogen peroxide, as explained in the document “Chemical etching of Siₗ₋ₓGeₓ in HF:H₂O₂:CH₃COOH”, T. K. Carns et al., J. Electrochem. Soc., vol. 142, N° 4, April 1995, for example. n-type doping of the second layer 4 (produced in SiGe) can be provided at the time of forming this layer in order to favor such etching.

Alternatively, dry etching of the CF₄-based isotropic plasma etching type could be used.

Reference can be made to the patent application FR 2 795 554 for more details on this type of process, used in that document in a different application.

Whatever the process used, it leads firstly to eliminating the second layer 4 in each of the regions provided with cylindrical holes 8, which starts the formation of cavities 9 replacing the second layer 4 in those regions, and secondly to attacking the residual portions of the second layer 4 as a result of the action of the etching from the cavities 9, so that the portions of the second layer 4 situated in the central region 7 are eliminated to form an extension 10 of each cavity 9. A passage 12 is provided in this way between the two cavities 9 via their respective extension 10.

Although the etching used preferentially attacks the second layer 4 produced in SiGe as just described, it also attacks, although less strongly, the layer situated in contact with the second layer 4, namely the first layer 2 and the third layer 6.

Nevertheless, because of the slower metabolism of the etching reaction with the first layer 2 and the third layer 6 formed in silicon, the thickness of material etched will depend greatly on the time of exposure of the area concerned to the reactive product such that the portions of these layers 2, 6 situated in the vicinity of the cylindrical holes 8 (through which the reactants penetrate) will be significantly etched (which leads to enlargement of the cavities 9); with CF₄-based dry etching, for example, the thickness eaten away is typically of the order of 10 to 50 nm for a lateral etch of 150 nm. On the other hand, the portions of these layers 2, 6 situated in the central region 7 will be etched to a lesser degree on moving away from the region of the cylindrical holes 8.

Because of this, the extensions 10 of the cavities 9 have a thickness that varies from the thickness of the cavity 9 concerned in that cavity to a thickness of the order of the initial thickness of the second layer 4 in the passage 12 (where there has been virtually no etching of the silicon layers 2, 6).

A structure as represented in section in FIG. 4 is obtained in this way.

It may be noted that the reduction of the thickness of the extensions 10 and the passage 12 in the central region 7 and the shape of this thickness reduction can be controlled by varying the concentration of germanium (Ge) in the second layer 4 produced in SiGe. Varying the concentration of germanium as a function of the depth in the layer influences the rate of elimination of the second layer 4 as a function of the depth concerned, which makes it possible to operate on the profile of the extensions 10 in vertical section.

For example, a uniform concentration of germanium in the second layer 4 will generate a steep profile between the portions of the extensions 10 generated only by eliminating the second layer 4 (portions close to the passage 12) and the portions of the extensions 10 generated by the combination of eliminating the second layer 4 and attacking the Si-n or Si-p layer 2,6 concerned.

On the other hand, continuous variation of the germanium concentration on passing from the doped silicon layer 2,6 concerned to the second layer 4 enables a more regular transition between the portion of the passage 12 formed by eliminating the second layer 4 and the extensions 10 formed by combining elimination of this same layer 4 and etching of the adjacent layers 2,6.

Once the cavities 9, the extensions 10 and the passage 12 have been formed as described hereinabove, there follows the filling of the cavities previously formed (cavities 9 and their extensions 10) and the residual portions of the cylindrical holes 8 with a dielectric material 14.

This filling is effected by infiltration of an insulator, for example, or by thermal oxidation of the structure (which fills the cavities with silicon dioxide), using techniques employed in other applications, for example as described in the patent application FR 2 800 913.

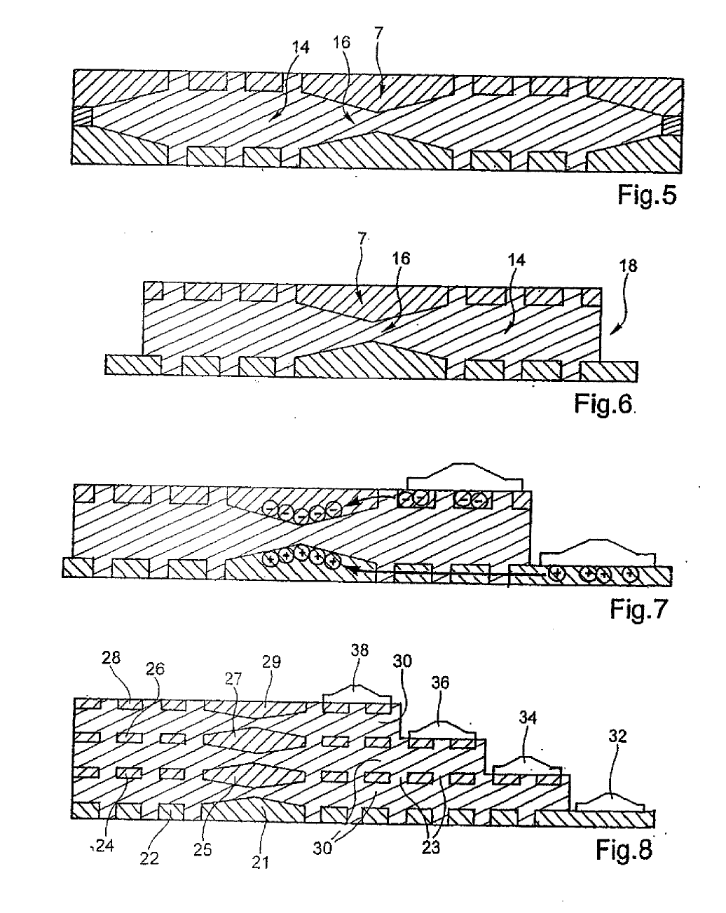

The structure represented in section in FIG. 5 is obtained in this way and therefore includes the basic elements of a capacitive junction (doped silicon layers separated by a dielectric material 14).

There follows etching of the external portions of the regions provided with holes (relative to the central region 7) to eliminate any residues of the SiGe second layer 4 and to obtain an insulation profile 14 of constant thickness except in the central region 7 where the thickness of insulation 16 is reduced as a consequence of the shape of the extensions 10 previously explained.

The structure that is then obtained is represented in FIG. 6. There can then follow the deposition of contacts, on the one hand on the third layer 6 (which retains an overall layer structure despite the presence of insulation at the locations where the cylindrical holes 8 were etched) and, on the other hand, the upper face of the first layer 2 bared during the preceding etching step.

A capacitive junction is formed in this way that comprises the Si-p first layer 2 and the Si-n third layer 6 separated by an intermediate layer 14 of insulative material that includes a thickness reduction 16 in the central region 7, compared in particular to the thickness of this same layer in the peripheral area that carries the contacts.

The thickness reduction is of the order of 20 to 60% here because of the method described hereinabove for forming the cavities.

This thickness reduction 16, which leads to a more intense electric field in the central region 7, produces a high concentration of charge carriers in the central region 7, and the capacitive junction produced in this way is therefore particularly suitable for producing a modulator, for example an optical modulator.

Such a modulator can easily be produced within an integrated optical structure, the waveguides whereof are formed by photonic crystal microcavities. In this case, the width of the reduced thickness area 16 in the dielectric layer 14 is of the order of the width of the microcavity forming the waveguide. This solution also enables etching of the holes 8 used in the method described hereinabove in the same technological step as the holes that form the photonic crystal in the silicon.

FIG. 8 represents a second embodiment of the invention in which a stack of capacitive junctions is used in the manner described hereinafter.

Such a multifunction structure comprises alternating layers 22, 26 of p-doped semiconductor material and layers 24, 28 of n-doped semiconductor material, between which a dielectric layer 30 is disposed.

In the example represented in FIG. 8, the multijunction structure includes two p-doped silicon layers 22, 26 (referred to hereinafter as Si-p layers 22, 26) and two n-doped silicon layers 24, 28 (referred to hereinafter as Si-n layers 24, 28).

The structure therefore has the following organization:

an Si-p layer 22;

a dielectric layer 30;

an Si-n layer 24;

a dielectric layer 30;

an Si-p layer 26;

a dielectric layer 30; and

an Si-n layer 28.

Such a structure is obtained, for example, by applying to the aforementioned stack of layers the technique explained with reference to the first embodiment, which does not entail any additional technological step compared to the situation in which only one junction is produced as described with reference to FIGS. 1 to 7.

Because of this, the doped silicon layers are crossed by holes 23 filled with dielectric material in two regions separating a central region 21, 25, 27, 29 of each layer 22, 24, 26, 28.

Each dielectric layer 30 comprises a thickness reduction in the central portion 21, 25, 27, 29 of the adjoining layers 22, 24, 26, 28. These thickness reductions are obtained using the technique explained with reference to the first embodiment for the production of each dielectric layer 30, for example.

Lateral etching of the same type as proposed in the first embodiment bares the upper face of each of the doped silicon layers 22, 24, 26, 28 and thus forms electrical contacts 32, 34, 36, 38 with each of those upper faces.

By energizing the multijunction structure that has just been described via the electrical contacts 32, 34, 36, 38, it is possible to control the accumulation of charge carriers present in the doped silicon layers 22, 24, 26, 28, which will be concentrated in particular in the central region 21, 25, 27, 29 of each layer thanks to the thickness reduction of the dielectric layer 30 concerned: there is obtained in this way an optical modulator that is particularly efficient thanks to this concentration of charge carriers in the central regions 21, 25, 27, 29 and the superposition of the capacitive junctions that produces the modulation effect over a relatively large thickness.

To obtain an even better accumulation of charge carriers in each of the junctions, all of the latter are connected in parallel by connecting the contacts 32, 36 associated with the Si-p layers 22, 26 to the same terminal of a voltage generator and the contacts 34, 38 associated with the Si-n layers 24, 28 to the opposite terminal of the generator.

The products and methods described hereinabove are merely non-limiting examples of the implementation of the invention.

1. A modulator including a capacitive junction crossed by an electromagnetic wave, the capacitive junction comprising at least one contact and one dielectric layer disposed between two semiconductor material layers, wherein the dielectric layer has a first thickness in the area of the electromagnetic wave that is less than a second thickness in the area of the contact and wherein the semiconductor material layers comprise monocrystalline semiconductor material.

2. The modulator according to claim 1, wherein at least one of the two semiconductor material layers is doped.

3. The modulator according to claim 1, wherein at least one of the two semiconductor material layers comprises silicon.

4. The modulator according to any one of claims 1 to 3, wherein the dielectric layer comprises silicon oxide or insulative polymer.

5. The modulator according to claim 1, wherein each of the two semiconductor material layers has a thickness of 30 nm to 500 nm.

6. The modulator according to claim 1, wherein the first thickness of the dielectric layer has a thickness of 2 nm to 30 nm.

7. The modulator according to claim 1, wherein the first thickness is from 20% to 60% less than the second thickness.

8. The modulator according to claim 1, wherein the capacitive junction comprises a plurality of dielectric layers separated by semiconductor material layers and wherein at least a portion of which are crossed by the electromagnetic wave.

9. A capacitive junction comprising a region adapted to be crossed by an electromagnetic wave, the capacitive junction further comprising a contact and a dielectric layer disposed between two semiconductor material layers wherein the dielectric layer has a first thickness in the region that is less than a second thickness in the area of the contact and wherein the semiconductor material layers comprise monocrystalline semiconductor material.

10. The capacitive junction according to claim 9, wherein at least one of the two semiconductor material layers is doped.

11. The capacitive junction according to claim 9, wherein at least one of the two semiconductor material layers comprises silicon.

12. The capacitive junction according to claim 9, wherein the dielectric layer comprises silicon oxide or insulative polymer.

13. The capacitive junction according to claim 9, wherein each of the two semiconductor material layers has a thickness of 30 nm to 500 nm.

14. The capacitive junction according to claim 9, wherein the second thickness of the dielectric layer is 2 nm to 30 nm.

15. The capacitive junction according to claim 9, wherein the first thickness reduction (16; 25, 27, 29) is 20% to 60% less than the second thickness.

16. A method of producing a capacitive junction, the method comprising the following steps:
epitaxially depositing a second layer and a third layer on a semiconductor material first layer, such that the third layer comprises a monocrystalline layer;
etching a region of the second layer and forming an etched space, wherein the etching is initiated in the second layer outside the region; and
filling the etched space with a dielectric material.

17. The method according to claim 16, wherein the second layer is disposed between two semiconductor material layers.

18. The method according to claim 17, wherein each of the two semiconductor material layers has a thickness of 30 nm to 500 nm.

19. The method according to claim 16, wherein the second layer has a thickness of 1 nm to 15 nm.

20. The method according to claim 16, further comprising a step of forming holes for access to the second layer outside the region, wherein the etching is initiated via the holes.

21. The method according to claim 16, wherein the etching is initiated in two area separated by the region to form a passage in the region.
